(19) United States
(12) Patent Application Publication
(10) Pub. No.: US 2005/0050257 A1
(43) Pub. Date: Mar. 3, 2005

(54) Nested locks to avoid mutex parking

(76) Inventor: Alexey Shakula, Reston, VA (US)

Correspondence Address: ROBERT M. MCDERMOTT, ESQ., 1824 FEDERAL FARM ROAD, MONTROSS, VA, 22520, US

(21) Appl. No.: 10/886,448

(22) Filed: Jul. 7, 2004

Related U.S. Application Data
(60) Provisional application No. 60/497,714, filed on Aug. 25, 2003.

(51) Int. Cl. G11C 5/00

(52) U.S. Cl. 711/1

(57) ABSTRACT

A native mutex lock of an operating system is embedded within an application-controlled spinlock. Each of these locks are applied to the same resource, in such a manner that, in select applications, and particularly in parallel processed applications, the adverse side-effects of the inner native mutex lock are avoided. In a preferred embodiment, each call to a system routine that is known to invoke a native mutex is replaced by a call to a corresponding routine that spinlocks the resource before calling the system routine that invokes the native mutex, then releases the spinlock when the system call is completed. By locking the resource before the native mutex is invoked, the calling task is assured that the resource is currently available to the task when the native mutex is invoked, and therefore the task will not be parked/deactivated by the native mutex.

This application claims the benefit of U.S. Provisional Application 60/497,714 filed 25 Aug. 2003.

### BACKGROUND AND SUMMARY OF THE INVENTION

This invention relates to the field of computer systems, and in particular to a method and program for efficiently accessing shared resources in a multiprocess, or multitask, system, such as a parallel processing system.

Resources within a multitask system are often configured to appear to be able to be available to multiple tasks simultaneously. A single network interface card on a node of a network, for example, provides a single communication channel to the network, but time-shares this channel among each of the tasks so that it appears that all of the tasks are communicating on the network ‘simultaneously’. In like manner, common memory, such as system memory, is time-shared among multiple tasks, and application memory is shared among multiple tasks in an application that is processed by multiple parallel tasks.

The sharing of memory, and other system resources, must be properly synchronized, to ensure that only one process is modifying or accessing the resource at the same time. For example, when a process adds an amount to a system variable, the process will typically read the value of the variable in the system memory, add the amount to it, and store the resultant sum to the system memory. If two processes each want to add an amount to the system variable, care must be taken so that each process retains control of the system memory from the time that the value is read until the time that the sum is stored. In like manner, if two processes write information/records to a file, care must be taken so that each process completes the writing of the entire record before the other process commences the writing of its record.

“Locks” are commonly provided by computer operating systems to prevent the simultaneous access to a resource by more than one task. When a task “locks” a resource, the operating system prevents other tasks from accessing the resource until the task “unlocks” the resource. The term “mutex” is commonly used to describe a mutual exclusion program object that allows a task to lock an associated resource to prevent other tasks from accessing the resource. Typically, a mutex bit is associated with each lockable resource; if the bit value is zero, the resource is unlocked, otherwise, it is locked. The task that sets the mutex to one is the only task that is permitted to set the mutex to zero.

In a straightforward embodiment, when a task desires access, it continually loops until the mutex bit is zero, then sets the bit to one, performs its intended process with the resource, then sets the bit to zero. Such a lock is termed a “spinlock”, in that it requires requesting tasks to loop, or “spin”, while waiting for the resource to be unlocked. This spinning, however, consumes processing time, as the processor repeatedly reads the bit to determine when the resource is unlocked. If other tasks subsequently attempt to access the resource, they will also place themselves in a spin mode, continually checking the status of the lock bit. In a simple time-slice multitasking system, if N tasks out of M total tasks are waiting for the resource, N/M of the total CPU cycles will be consumed in merely reading the lock bit, as each of the N tasks merely spin during their allocated time-slice.

To avoid the inefficiencies of spinlocks, conventional operating systems provide mechanism for queuing tasks that are waiting for a locked resource. When a task attempts to access a mutex-locked resource, the operating system detaches the task from execution (“parks” the task), and places the task in a first-in-first-out queue. When the resource is unlocked, by the task that initially locked the resource, the next task in the queue is reactivated (“unparked”), granted access to the resource, and the resource is again locked. In this manner, if N out of M tasks are waiting for the resource, they will be parked, and the CPU cycles will be allocated among the M−N active/unparked tasks.

Generally, the parking of tasks that are awaiting access to a locked resource is performed automatically by a multitask processor, and is transparent to the application-level program. For the purposes of this disclosure, the term “native mutex” is used hereinafter to define a mutex scheme that is provided by an operating system to provide CPU-efficient access control to a resource by automatically parking tasks that are waiting to access a currently-accessed resource.

The automatic parking of native mutex schemes also allows the multitask processor to allocate access to a resource fairly, or to allocate access to the resource based on a priority scheme, and so on. U.S. Pat. No. 6,480,918, “LINGERING LOCKS WITH FAIRNESS CONTROL FOR MULTI-NODE COMPUTER SYSTEMS”, 12 Nov. 2002; U.S. patent application Publication Ser. No. 2003/0041183 “SYNCHRONIZATION OBJECTS FOR MULTI-COMPUTER SYTEMS”, 27 Feb. 2003; and U.S. patent application Publication Ser. No. 2003/0131168, “ENSURING FAIRNESS IN A MULTIPROCESSOR ENVIRONMENT USING HISTORICAL ABUSE RECOGNITION IN SPINLOCK ACQUISITION”, 10 Jul. 2003, are examples of embodiments of native mutex schemes in conventional operating systems, and are each incorporated by reference herein.

Although native mutex schemes provide for overall CPU efficiency, they do not necessarily result in performance efficiency for a given application program, due to the overhead associated with the parking/unparking process. In some instances, an application program may experience a 10:1 or even 100:1 degradation in speed due to native mutex conflicts. In some applications, such as real-time processing, such degradation may prevent the application from performing its function, and in other applications, such as the simulation of complex systems, such degradation may extend the elapsed time beyond feasible limits. Although a priority-based mutex scheme may alleviate some of this degradation, the improvement in performance provided by a higher priority may not be sufficient to provide adequate performance. Additionally, a priority-based system is generally ineffective if the multiple tasks that are competing for the resource are associated with a single application on a parallel processor system, because the priority is generally allocated per application, not per sub-task within an application.

In many instances, applications that require efficient processing must forego the advantages provided by conventional operating systems, because of the side-effects caused by native functions within the operating system, such as the side-effect of queuing and parking produced by the operating system's implementation of a “fair” resource sharing technique. In such instances, the developer must either find another operating system that does not have the particular side effect that degrades the application program's performance, or must custom design an operating system to avoid such side effects.

An objective of this invention to provide a means of avoiding the inefficiencies and overhead associated with native mutexes of conventional operating systems. A further objective of this invention is to provide a means of avoiding the inefficiencies associated with native mutexes without requiring major changes to application programming techniques. It is a further objective of this invention to provide a means of automatically improving the performance of existing application programs.

These objectives, and others, are achieved by embedding native mutex locks within an application-controlled lock. Each of these locks are applied to the same resource, in such a manner that, in select applications, and particularly in parallel processed applications, the adverse effects of the inner native mutex lock are avoided. In a preferred embodiment, each call to a system routine that is known to invoke a native mutex is replaced by a call to a corresponding routine that spinlocks the resource before calling the system routine that invokes the native mutex, then releases the spinlock when the system call is completed. By locking the resource before the native mutex is invoked, the calling task is assured that the resource is currently available to the task when the native mutex is invoked, and therefore the task will not be parked by the native mutex.

### BRIEF DESCRIPTION OF THE DRAWINGS

The invention is explained in further detail, and by way of example, with reference to the accompanying drawings wherein:

FIG. 1 illustrates an example flow diagram of an application program that accesses a shared resource using a conventional native mutex control technique.

FIG. 2 illustrates an example flow diagram of an application program that accesses a shared resource using the nested spinlock and native mutex control technique of this invention.

FIG. 3 illustrates an example flow diagram of a conventional native mutex control technique for accessing a shared resource.

FIG. 4 illustrates an example flow diagram of a nested spinlock and native mutex control technique for accessing a shared resource in accordance with this invention.

Throughout the drawings, the same reference numerals indicate similar or corresponding features or functions. The drawings are included for illustrative purposes and are not intended to limit the scope of the invention.

### DETAILED DESCRIPTION OF THE INVENTION

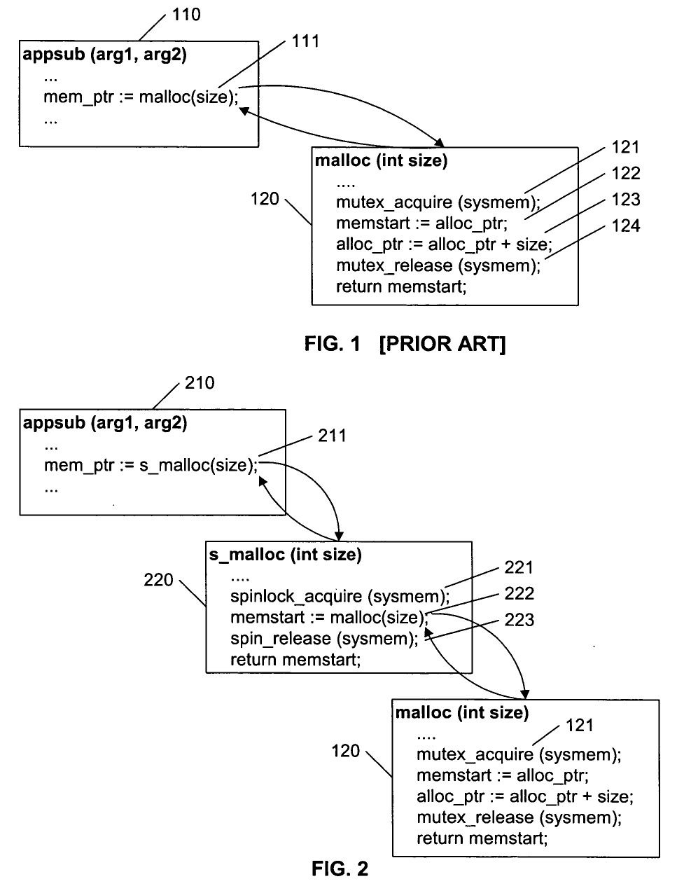

FIG. 1 illustrates an example flow diagram of an application program 110 that accesses a shared resource using a conventional native mutex control technique. In this example, the conventional “malloc” (memory allocation) function 120 is used as an example system function that includes a native mutex control technique. This example function 120 is intended to illustrate a function or subroutine that is beyond the control of the developer of the application program 110. The function 120 may be provided, for example, as an internal function of the operating system, and/or included in a set of library functions provided in a program development system, and/or provided by another source, such as a configuration management system that enforces standardization among program developers by defining approved interface standards.

By way of background, the conventional malloc function 120 allocates a block of system memory (sysmem) to a process 110 upon request for a desired size of the memory block. All tasks that require memory allocation from the system memory call this function 120. A pointer (alloc_ptr) is maintained by the system that controls the memory, and is configured to point to the next available unallocated memory location. Assuming a sequential allocation of memory, the start of the allocated memory block (memstart) will be the pointer's current value, at 122, and the pointer will be advanced by the size of the allocated block, at 123, in preparation for the next call for memory allocation, by the same task or any other task. Note that if another task simultaneously calls for a memory allocation, between steps 122 and 123, and access to the allocation pointer (alloc_ptr) is not controlled, this other task would read the same value from alloc_ptr as the first task, and both tasks would use that location as the start of its allocated memory. To prevent the allocation of the same memory to multiple tasks, the allocation pointer (alloc_ptr) is controlled within the malloc function by a native mutex function, at 121 and 124.

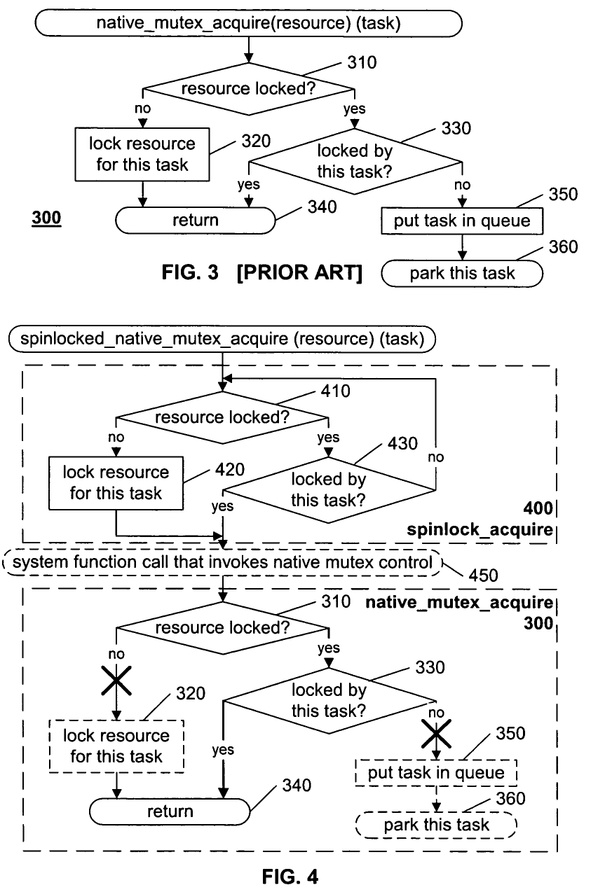

At 121, the mutex_acquire function is called, to request a lock on the system memory, the resource to which the allocation pointer (alloc_ptr) is associated. As discussed above, and as detailed below with regard to FIG. 3, the native mutex_acquire function either grants exclusive access to the resource, or places the calling task in a queue until the resource is available. While in the queue, the task is de-activated, or ‘parked’. When the resource becomes available, either immediately, or after processing each of the tasks ahead of this task in the queue, it is reactivated, and the resource (system memory, including alloc_ptr) is exclusively controlled by this task. Thereby, it is assured that the reading and updating of alloc_ptr at 122 and 123 occurs without interference from other tasks.

At 124, the mutex_release function is called, to release the lock on the system memory. If any tasks remain in the queue, the system memory is assigned to the next task in the queue, or to a task in the queue that is given higher priority than the default first-in first-out queuing scheme.

Note that the example malloc function 120 assures that only one task accesses the system memory at any given time, independent of the particular calling task 1 10. Other system-provided or library-provided functions employ similar techniques for protecting shared resources from simultaneous use. The calling task 110 has no control over how the exclusive control of the resource is provided by the provided function 120, and thus cannot directly overcome any inefficiencies that the function 120 may introduce to the calling tasks. As noted above, a variety of schemes have been proposed for assuring that multiple tasks are given an equal opportunity to access each resource, or, in the case of priority-based queue processing, that high priority tasks are given appropriately more or quicker access to each resource, but these schemes are also beyond the tasks' direct control, so that if inefficiencies result, the conventionally programmed tasks have no direct means of avoiding such inefficiencies.

The parallel processing of a multitask process often suffers from the inefficiencies of the use of native mutex techniques to control access to a shared resource, due to the overhead associated with parking and unparking tasks that call for access to currently-locked resources. Consider, for example, partitioning a multitask process having M tasks that are distributed among N processors that operate in parallel and share a common resource, such as allocate-able system memory. If K tasks request access to the resource concurrently, K−1 tasks will be put on the queue and deactivated/parked, leaving M−(K−1) active tasks. If the number of remaining active tasks is equal to or greater than N, then the N processors will be productively used. If, on the other hand, the number of active tasks is less than N, a number (N−(M−(K−1))) of processors will be unused, and thus the overhead associated with parking and unparking the (N−(M−(K−1))) tasks will have been needlessly incurred.

Consider also a single application running on N processors with a sufficient number of tasks M to keep the N processors occupied continuously. Assume that, on average, there are L concurrent requests for a particular single-access asset, that each access incurs T1 time units, and that the parking/unparking tasks incurs T2 time units. Without a native mutex, each of the L concurrent requests will wait (L−1)*T1 time units before gaining access to the asset. While each of the L tasks are waiting, L other tasks will not be processed by the processors that are being used for these L tasks. With a native mutex, L−1 of these other tasks will be processed while L−1 tasks are parked. The cost of parking/unparking these L−1 tasks is (L−1)*T2 time units, and the gain in processing the other tasks will be (L−1)*(L−1)*T1 time units. Therefore, if (L−1)²*T1 is greater than (L−1)*T2, an overall gain is achieved; otherwise, the parking/unparking overhead exceeds the gain provided by the native mutex. Stated in another way, if the average number of concurrent accesses L is greater than one and less than (T2+T1)/T1, the parking/unparking overhead caused by the native mutex will result in an overall inefficiency.

As noted above, an objective of this invention is to avoid the inefficiencies that are introduced by native mutex schemes. As also noted above, however, many system and library functions contain calls to native mutex function, and these system and library functions, as well as the native mutex functions, are beyond the direct control of an application program developer.

In accordance with a first aspect of this invention, each system or library function that employ a native mutex process that causes inefficiencies, or is expected to cause inefficiencies, due to the parking and unparking of active process, is encapsulated within another function that is specifically designed to prevent the native mutex process from parking the active process.

FIG. 2 illustrates an example flow diagram of an application program 210 that accesses a shared resource using the nested spinlock 220 and native mutex 120 control technique of this invention. The application program 210 of FIG. 2 differs from the program 110 of FIG. 1 in that each call 111 to the example system function malloc 120 in FIG. 1 is replaced by a call 211 to an encapsulating function s_malloc 220 in FIG. 2.

The encapsulating function s_malloc 220 performs the same operational function as the replaced function 120 in the application program 210, and thus the operation of the application program 210 in FIG. 2 is equivalent to the operation of the application program 110 in FIG. 1. However, the encapsulating function s_malloc 220 includes calls 221, 223 to spinlock_acquire and spinlock_release functions before and after the call 222 to the replaced malloc function 110, respectively, to improve the performance of the application program 210 compared to the program 110 by preventing the called malloc function 110 from parking the calling process 210. This prevention of parking caused by a native mutex lock by nesting the lock within a redundant lock is best understood with reference to FIGS. 3 and 4.

FIG. 3 illustrates an example flow diagram of a conventional native mutex control technique 300 for accessing a shared resource, and FIG. 4 illustrates an example flow diagram of a nested spinlock 400 and native mutex 300 control technique for accessing a shared resource in accordance with this invention.

When a native mutex control technique 300 receives a request to acquire a mutex resource from a particular task, the resource is checked to determine whether it is already locked, at 310. If, at 310, the resource is not locked, the resource is locked for use by the requesting task, at 320, and control returns to the calling routine, at 340 (in the example of FIGS. 1 and 2, control is returned to the malloc function 120). If the resource is locked, the resource is further checked to determine the task to which the resource is locked, at 330. If, at 330, it is determined that the resource is already locked to the requesting task, no action is taken, and control again returns to the calling routine, at 340.

If the resource is locked by another task, an identification of the requesting task is placed in an access queue for this resource, at 350, and the task is deactivated/parked, at 360. Control does not return to the calling routine until this task rises to the top of the queue, the resource becomes unlocked from its prior task and locked to this task, and the task is reactivated/unparked (not illustrated). As noted above, this queuing 350, parking 360, and unparking (not illustrated) process can introduce a significant degradation in the performance of applications that frequently seek access to shared resources, because generally these processes consume orders of magnitude more time than the locking 320 and unlocking (not illustrated) processes that are invoked when the resource is immediately available for locking by the requesting task.

FIG. 4 illustrates an example flow diagram of a nested spinlock 400 and native mutex 300 control technique for accessing a shared resource in accordance with this invention, corresponding to the example steps 221-222 in the flow diagram of FIG. 2.

For the purposes of this disclosure, the term “spinlock” is defined as any locking scheme that facilitates the locking of a resource to a requesting task without the possibility of deactivating or parking the requesting task. Conversely, the term “native mutex”, or “native mutex lock” is defined as any locking scheme that facilitates the locking of a resource to a requesting task when the resource next becomes available, and also facilitates the queuing and deactivation of the task while the resource is unavailable. In accordance with this invention, a spinlock 400 is placed before a call to a system function 450 that includes a call to a native mutex lock 300 that is expected to degrade the performance of the application by parking and unparking tasks within the application.

The spinlock_acquire function 400 initially determines whether the requested resource is locked, at 410, and if it is not currently locked, locks the resource to the requesting task, at 420, and returns control to the calling program (e.g. 220 in FIG. 2, at the end of step 221). If the resource is currently locked to the requesting task, at 430, no action is taken, and control is returned to the calling program. If the resource has been locked to a different task, at 430, the program loops back to 410, to determine again whether the resource remains locked. This 410-403 looping/“spinning” continues until the resource becomes unlocked and locked to the requesting task, at 420.

Note that this spinlock process 400 does not place the calling task in a queue, and does not park the task until the resource becomes available. In principle, this spinlock process could lead to program inefficiency, because the requesting task competes with every other process that is attempting to access the resource, and there is no guarantee that the requesting task will ever get out of the loop 410-430. However, in certain applications, discussed below, this spinlock process 400 increases the program efficiency by preventing the subsequently called native mutex lock 300 from parking the requesting task.

Upon acquiring spinlock to the resource, the original system function call 450 (malloc, in the example call at 222 in FIG. 2) is made, which leads to a call to the native_mutex_aquire function 300 (step 121 in FIG. 2). As illustrated in FIG. 4, this function 300 is identical to the prior art native_mutex_acquire function 300 in FIG. 3. However, as illustrated by the “X”s in the branches from steps 310, 330, the native_mutex_acquire function 300 returns without taking any action, and, particularly, without placing the requesting task in a queue and without deactivating/parking the requesting task.

Because the call to the native_mutex_acquire function 300 occurs after the resource is locked to the requesting task by the spinlock function 400, the “resource locked?” test, at 310, must result in a “yes”, and the “locked by this task”, at 330, must also result in a “yes”, thereby preventing a branch to the queuing and parking steps 350-360 that produce program inefficiencies. Therefore, with reference to FIG. 2, by encapsulating the system call 222 that invokes a native mutex lock 121 within a spinlock 221, 222, program inefficiencies caused by the queuing and parking processes of a native mutex lock.

As noted above, the use of the spinlock function 400 can result in program inefficiencies, particularly if the requested resource is continually requested by many other competing processes. However, there are particular situations wherein the use of the spinlock 400 before a call to a native mutex 300 can provide significant performance improvements.

Of particular note, consider an application program that is executed on multiple processors using parallel processing techniques. Often, such parallel processing is performed because the application program requires it to perform its task properly (e.g. real time processing systems), or because the turn-around time of the application program using a single processor would prove impractical (e.g. simulation of large systems). Generally, because of the need for fast processing, these applications are given priority over other processes that are run on the parallel-processing system, and/or are run alone, or almost alone, on the system. In these situations, the application program primarily competes with itself for access to common resources, in that the only tasks, or the large majority of tasks, that are competing for the resource are the sub-tasks of the application program that are each being run as a parallel task.

If a particular resource is “saturated” or “over tasked”, i.e. there are more requests for the resource per unit time than the system can provide, or near being over tasked, the use of a spinlock 400 as taught in this disclosure will, in general, degrade the performance of the application. If, on the other hand, the particular resource is “moderately tasked”, or “lightly tasked”, the use of the spinlock 400 to encapsulate system calls as taught in this disclosure can be expected to substantially improve the performance of the application, by avoiding the queuing and parking of sub-tasks when the resource is temporarily unavailable.

This invention can be embodied in an existing application in a relatively straightforward manner. When a particular system routine is identified as being the cause of inefficiencies related to native mutex queuing and parking, the source code of the application program can be searched for each call to the system routine, and replaced by a substitute call to the routine that encapsulates the system routine within a spinlock. The encapsulating routine is created within the application program and/or within a supporting library of subroutines and functions, and the original calls to the system routine are replaced by calls to this encapsulating routine. In the example of FIG. 1, each occurrence of the function “malloc” in the original source 110 is replaced, using a conventional text editor, with the created encapsulating function “s_malloc”, as illustrated by the source 210 in FIG. 2. Thereafter, the amended source code is recompiled, and the flow of the resultant program will be as illustrated in FIG. 2.

Alternatively, if the source code of the existing application is not available for modification, or not permitted to be modified, the object code of the application can be amended by replacing each branch to the address of the system routine by a branch to the address of the encapsulating routine. In like manner, the symbolic address of the system routine can be mapped to the address of the encapsulating routine in the linker/loader that is used to create the object code from the compiled code. These and other techniques for replacing calls to a given system routine to a routine that encapsulates the system routine within a spinlock will be evident to one of ordinary skill in the art.

The foregoing merely illustrates the principles of the invention. It will thus be appreciated that those skilled in the art will be able to devise various arrangements which, although not explicitly described or shown herein, embody the principles of the invention and are thus within the spirit and scope of the following claims.

In interpreting these claims, it should be understood that:
a) the word “comprising” does not exclude the presence of other elements or acts than those listed in a given claim;
b) the word “a” or “an” preceding an element does not exclude the presence of a plurality of such elements;
c) any reference signs in the claims do not limit their scope;
d) several “means” may be represented by the same item or hardware or software implemented structure or function;
e) each of the disclosed elements may be comprised of hardware portions (e.g., including discrete and integrated electronic circuitry), software portions (e.g., computer programming), and any combination thereof;
f) hardware portions may be comprised of one or both of analog and digital portions;
g) any of the disclosed devices or portions thereof may be combined together or separated into further portions unless specifically stated otherwise; and
h) no specific sequence of acts is intended to be required unless specifically indicated.

1. A method of controlling access to a resource, comprising:
acquiring a spinlock on the resource,
acquiring a native mutex lock on the resource,
accessing the resource,
releasing the native mutex lock, and
releasing the spinlock.

2. The method of claim 1, further including:
invoking a system routine after acquiring, and before releasing, the spinlock,
wherein
the system routine is configured to acquire, and release, the native mutex lock.

3. The method of claim 2, wherein
the native mutex lock is configured to selectively deactivate a process when the resource is unavailable for access, and
the spinlock prevents the native mutex lock from deactivating the process by assuring that the resource is available for access.

4. The method of claim 3, wherein
the spinlock is configured to maintain the process in an active state until the resource is available for access.

5. The method of claim 4, wherein
the acquiring and releasing of the native mutex lock is automatically performed by an operating system of a computing system that is executing this method.

6. The method of claim 1, wherein
the native mutex lock is configured to selectively deactivate a process when the resource is unavailable for access, and
the spinlock prevents the native mutex lock from deactivating the process by assuring that the resource is available for access.

7. The method of claim 6, wherein
the spinlock is configured to maintain the process in an active state until the resource is available for access.

8. The method of claim 7, wherein
the acquiring and releasing of the native mutex lock is automatically performed by an operating system of a computing system that is executing this method.

9. The method of claim 1, wherein
the acquiring and releasing of the native mutex lock is automatically performed by an operating system of a computing system that is executing this method.

10. A method of improving performance of an application program, comprising:
creating an encapsulating function that includes a target function within a spinlock for a resource, and
replacing each reference to the target function in the application program with a reference to the encapsulating function, so that the application program invokes the spinlock before invoking the target function,
wherein
the target function is configured to invoke a native mutex lock for the resource.

11. The method of claim 10, further including
identifying the target function by assessing a likelihood of degradation of the performance of the application program caused by deactivation of a task of the application program during execution of the native mutex lock.

12. The method of claim 11, wherein
the target function is included in an operating system that is not modifiable by a user of the operating system.

13. The method of claim 12, wherein
replacing each reference to the target function includes editing a source of the application program to replace each occurrence of a name of the target function with a name of the encapsulating function.

14. The method of claim 10, wherein
replacing each reference to the target function includes editing a source of the application program to replace each occurrence of a name of the target function with a name of the encapsulating function.

15. The method of claim 10, wherein
replacing each reference to the target function includes editing code of the application program to replace each occurrence of an address of the target function with an address of the encapsulating function.

16. The method of claim 10, wherein
replacing each reference to the target function includes a mapping of a symbolic name of the target function to an address of the encapsulating function.

17. An application program, comprising:
an encapsulating routine that encapsulates a target routine within a spinlock for a resource, and
a plurality of calls to the encapsulating routine,
wherein
the target routine is configured to invoke a native mutex lock for the resource.

18. The application program of claim 17, wherein
the target routine includes a system routine that is provided by an operating system.

19. The application program of claim 17, wherein
the native mutex lock is configured to selectively deactivate a process of the application program when the resource is unavailable for access, and
the spinlock prevents the native mutex lock from deactivating the process by assuring that the resource is available for access before the native mutex lock is invoked.

20. The application program of claim 19, wherein
the spinlock is configured to maintain the process in an active state until the resource is available for access.
